(19) United States
(12) Patent Application Publication
(10) Pub. No.: US 2009/0268382 A1
(43) Pub. Date: Oct. 29, 2009

(54) BUTTON STRUCTURE

(75) Inventors: XIANG-GUO ZHAO, Shenzhen City (CN); CHIH-CHIANG CHANG, Shindian (TW)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (Hong Kong) Limited, Kowloon (HK)

(21) Appl. No.: 12/407,886

(22) Filed: Mar. 20, 2009

(30) Foreign Application Priority Data
Apr. 28, 2008 (CN) 200810301359.7

(51) Int. Cl. H05K 7/00

(52) U.S. Cl. 361/679.01

(57) ABSTRACT

A button structure for a portable electronic device includes a housing defining a button hole, a button received in the button hole, and a seal member of elastic material. The seal member is fixed on the housing and seals the button hole.

### BACKGROUND

1. Technical Field

The present disclosure relates to button structures, and particularly to a waterproof and dustproof button structure used in a portable electronic device.

2. Description of Related Art

Many portable electronic devices such as mobile phones comprise a housing with an interior compartment receiving a printed circuit board (PCB) therein. The device often includes a button structure for directing various operations. Typically, the button structure includes a key cover and a key cap adhered thereto having elastic characteristics. The key cap can be deformed by external force applied thereto and then resume its original state upon removal of the force. The button structure is received in a hole defined in a face of the device, and a slight gap exists between the button structure and the outer wall. Moisture can easily enter the device interior through the gap of the button structure, thus affecting the printed circuit board in the portable electronic device. In addition, dust entering the portable electronic device through the gap can seriously affect performance of the device would and even cause permanent damage to the device.

Therefore, there is room for improvement within the art.

### BRIEF DESCRIPTION OF THE DRAWINGS

Many aspects of the disclosure can be better understood with reference to the following drawings. The components in the drawing are not necessarily drawn to scale, the emphasis instead being placed upon clearly illustrating the principles of the button structure. Moreover, in the drawing like reference numerals designate corresponding parts throughout the several views, in which:

FIG. 1 is a schematic view of a button structure assembled to a housing in accordance with an exemplary embodiment;

FIG. 2 is a cross-section taken along line II-II of FIG. 1;

FIG. 3 is an exploded view of the button structure of FIG. 1; and

FIG. 4 is similar to FIG. 3, but viewed from another aspect

### DETAILED DESCRIPTION OF THE EXEMPLARY EMBODIMENTS

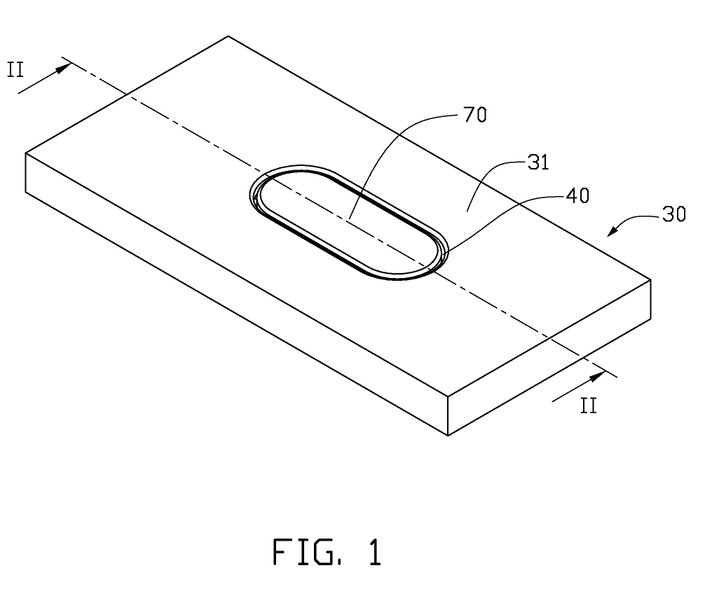

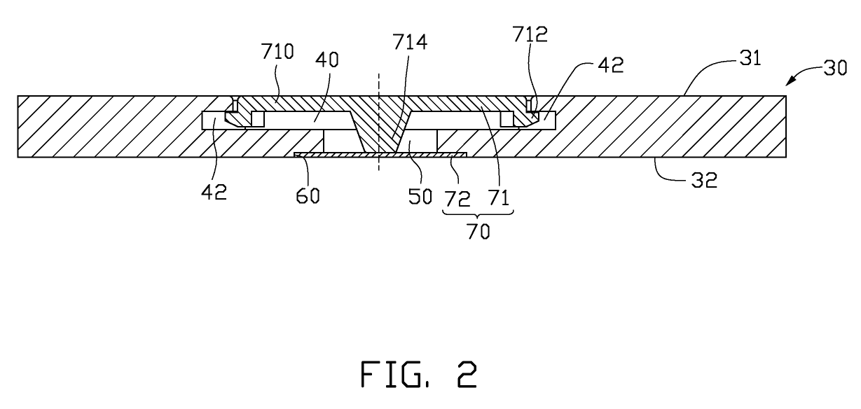

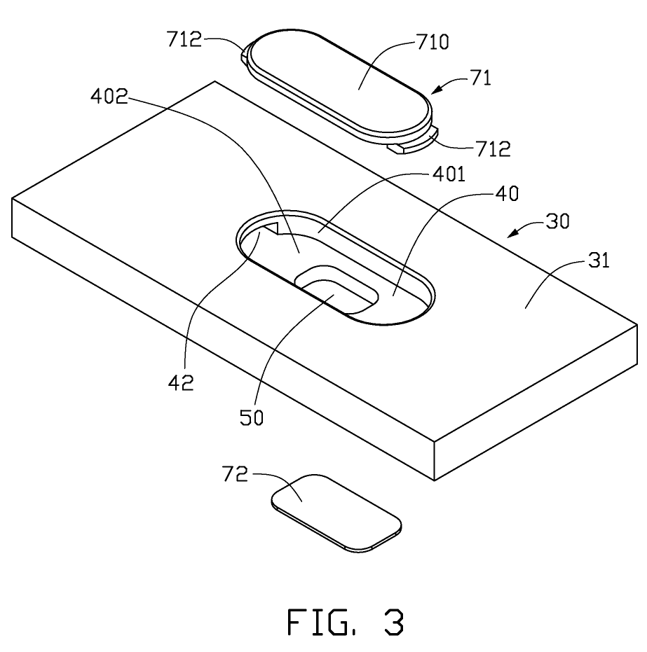

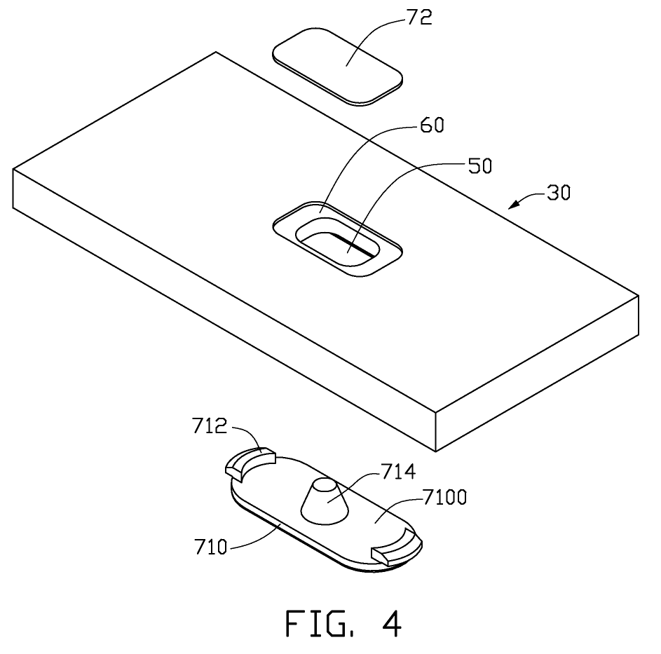

FIGS. 1 and 2 show an exemplary embodiment of a button structure 70 used in a housing 30 of a portable electronic device. The housing 30 includes a top portion 31 and a bottom portion 32 formed at an opposite side thereof. The top portion 31 defines a chamber 40 therein. Referring to FIGS. 3 and 4, the chamber 40 is generally elliptical, and is cooperatively surrounded by an inner peripheral wall 401 and a bottom wall 402. Two symmetrical receiving grooves 42 are defined in the inner peripheral wall 401 of the chamber 40. The bottom wall 402 of the chamber 40 defines a hole 50 therein. The hole 50 passes through the top portion 31 and the bottom portion 32. The bottom portion 32 defines a slot 60 communicating with the hole 50.

The button structure 70 includes an assembly 71 and a seal member 72. The assembly 71 includes a contact portion 710, two latching portions 712 and a protruding portion 714. The contact portion 710 is substantially rectangular and includes an inner surface 7100. Each of the latching portions 712 extends from one side of the inner surface 7100 and horizontally align with each other. The latching portions 712 can be respectively received into receiving grooves 42 of the housing 30. The protruding portion 714 is conical and symmetrically positioned on a center of the inner surface 7100. The largest diameter of the protruding portion 714 is smaller than the hole 50, allowing passage thereof therethrough. The seal member 72 is elastic material, such as rubber, and is deformable by external force. The seal member 72 is positioned in the slot 60 to seal the hole 50. The seal member 72 of the exemplary embodiment is integrally formed with the housing 30 by double shot injection mold.

In assembly, the latching portions 712 are respectively received into the receiving grooves 42 and the protruding portion 714 passes through the hole 50 to abut the seal member 72 and form the button structure 70.

In use, the assembly 71 is impelled by external force towards the bottom wall 402 of the chamber 40. The protruding portion 714 ejects the seal member 72 from it original state to provide access to electronic components (not shown) under the seal member 72. Meanwhile, the seal member 72 is deformed by the external force. When the external force is removed, the seal member 72 returns to its original state. Thus, the seal member 72 returns the assembly 71 to its original state.

Since the seal member 72 is integrally formed with the housing 30, the housing 30 and the seal member 72 are tightly sealed with no gap, preventing moisture and/or dust from entering thereinto.

It is to be understood that the chamber 40 and the hole 50 can be constituted as a button structure hole to receive the assembly 71.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A button structure for use in an electronic device, the electronic device comprising a housing defining a button hole therein, the button structure comprising:
a button received in the button hole; and
a seal member of elastic material;
wherein the seal member is fixed on the housing and seals the button hole.

2. The button structure as claimed in claim 1, wherein the seal member is integrally formed with the housing by double shot injection mold.

3. The button structure 1 as claimed in claim 2, wherein the seal member is rubber.

4. The button structure as claimed in claim 1, wherein the button hole includes a chamber and a hole, with the button received in the chamber and the hole.

5. The button structure as claimed in claim 4, wherein the housing defines a slot communicating with the hole.

6. The button structure as claimed in claim 5, wherein the seal member is fixed in the slot.

7. The button structure as claimed in claim 4, wherein the chamber is surrounded by an inner peripheral wall, the inner peripheral wall defines two receiving grooves, the button comprises a contact portion, from which two latching portions extend, the contact portion is accommodated in the chamber, and the latching portions are respectively received in the receiving grooves.

8. The button structure as claimed in claim 7, wherein the button comprises a protruding portion positioned on the contact portion and above the hole.

9. An electronic device, comprising:
a housing defining a button hole and two receiving grooves therein;
a button received in the button hole, the button including two latching portions; and
a seal member of elastic material;
wherein the seal member is fixed on the housing and seals the button hole, the latching portions being respectively received in the receiving grooves.

10. The electronic device as claimed in claim 9, wherein the seal member is integrally formed with the housing by double shot injection mold.

11. The electronic device as claimed in claim 10 wherein the seal member is rubber.

12. The electronic device as claimed in claim 9, wherein the button hole has a chamber defining a hole therethrough, and the button is received in the chamber and the hole.

13. The electronic device as claimed in claim 12, wherein the housing defines a slot communicating with the hole.

14. The electronic device as claimed in claim 13, wherein the seal member is fixed in the slot.

15. The electronic device as claimed in claim 15, wherein the button comprises a protruding portion positioned on the contact portion and above the hole.
